(19) United States
(12) Patent Application Publication
(10) Pub. No.: US 2026/0020298 A1
(43) Pub. Date: Jan. 15, 2026

(54) SEMICONDUCTOR ARRANGEMENT WITH ISOLATED DEVICE REGIONS

(71) Applicant: Infineon Technologies Dresden GmbH & Co. KG, Dresden (DE)

(72) Inventors: Rolf Weis, Dresden (DE); Marco Müller, Pirna (DE)

(21) Appl. No.: 19/261,424

(22) Filed: Jul. 7, 2025

(30) Foreign Application Priority Data
Jul. 12, 2024 (DE) 102024119940.7

(51) Int. Cl. H10D 62/10; H01L 21/761

(52) U.S. Cl. CPC H10D 62/114; H01L 21/761

(57) ABSTRACT

A semiconductor arrangement is disclosed. The semiconductor arrangement includes a semiconductor layer having a first surface; a buried region of a first doping type formed in the semiconductor layer spaced apart from the first surface; an isolating grid extending from the first surface to the buried region and including a first region of the first doping type; and device regions of the second doping type adjoining the buried region and isolated from each other by the isolating grid.

### TECHNICAL FIELD

This disclosure relates in general to a semiconductor arrangement with isolated device regions.

### BACKGROUND

Electronic circuits may include a plurality of semiconductor devices. In many applications, in order to save space and cost, it is desirable to implement several semiconductor devices of an electronic circuit in one semiconductor body (die). The individual semiconductor devices integrated in one semiconductor body can have different voltage blocking capabilities. Furthermore, the individual semiconductor devices can belong to different voltage domains of the electronic circuit. Each “voltage domain” is defined by the electrical potential to which voltages occurring in the respective domain are referenced to. The individual semiconductor devices can be interconnected through electrically conducting lines formed above the semiconductor body.

In order to prevent an unintended current to flow between the individual devices within the semiconductor body, each device is usually arranged in a device region that is isolated from the other device regions by junction isolations. Usually, each device region includes its designated junction isolation.

Each junction isolation consumes space in the semiconductor body. There is a need for providing a space-saving semiconductor arrangement with isolated device regions.

### SUMMARY

One example relates to a semiconductor arrangement. The semiconductor arrangement includes a semiconductor layer having a first surface, a buried region of a first doping type formed in the semiconductor layer spaced apart from the first surface, an isolating grid extending from the first surface to the buried region and including a first region of the first doping type; and device regions of the second doping type adjoining the buried region and isolated from each other by the isolating grid.

Those skilled in the art will recognize additional features and advantages upon reading the following detailed description, and upon viewing the accompanying drawings.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 illustrates a vertical cross-sectional view of a semiconductor arrangement that includes a buried region formed in a semiconductor layer and an isolating grid adjoining the buried region and defining device regions in the semiconductor layer;

FIGS. 2-5 show top views of semiconductor arrangements of the type illustrated in FIG. 1 according to different examples;

FIGS. 6A-6B illustrate one example of a method for forming the buried region;

FIGS. 7A-7C illustrate another example of a method for forming the buried region;

FIGS. 8A-8C illustrate one example of a method for forming the isolating grid;

FIGS. 9A-9B illustrate optional process steps in the method according to FIGS. 8A-8C;

FIGS. 10A-10B illustrate a T-shaped portion of the isolating grid according to one example;

FIGS. 11A-11C illustrate vertical cross-sectional views of the T-shaped portion according to FIG. 10A at different positions;

FIGS. 12-13 illustrate a transistor device according to one example that is integrated in a device region;

FIG. 14 illustrates a modification of the transistor device illustrated in FIG. 13;

FIG. 15 shows a top view of a device region in which several transistor devices are integrated;

FIG. 16 illustrates a modification of the transistor device illustrated in FIGS. 12-13;

FIGS. 17-18 illustrate a transistor device according to another example that is integrated in a device region; and

FIG. 19 illustrates a modification of the transistor device illustrated in FIGS. 17-18.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

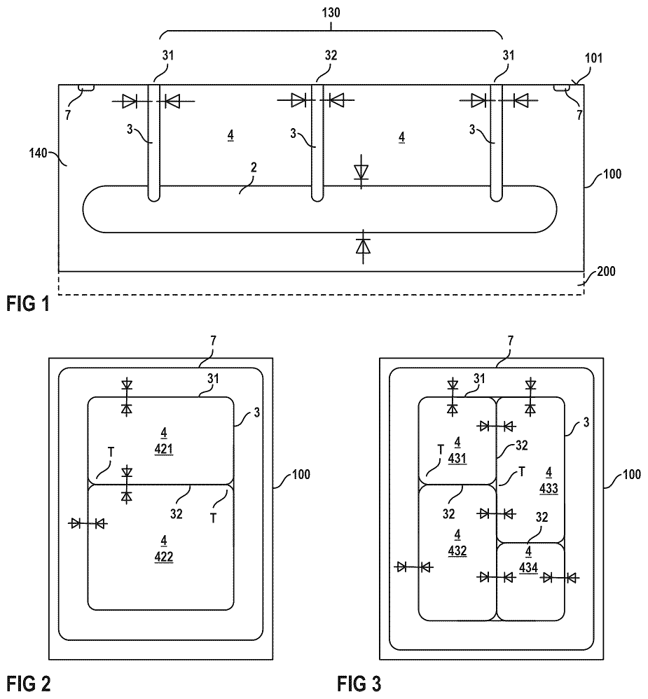

FIG. 1 schematically illustrates a vertical cross-sectional view of a semiconductor arrangement according to one example. FIGS. 2-5 illustrate top views of semiconductor arrangements of the type illustrated in FIG. 1 according to different examples.

Referring to FIGS. 1-5, the semiconductor arrangement includes a semiconductor layer 100 with a first surface 101, a buried region 2 of a first doping type formed in the semiconductor layer 100 spaced apart from the first surface 101, an isolating grid extending from the first surface 101 to the buried region 2, and device regions 4. The device regions 4 are of a second doping type complementary to the first doping type, adjoin the buried region 2, and are isolated from each other by the isolating grid 3.

The semiconductor layer 100 is a monocrystalline semiconductor layer, for example. According to one example, the semiconductor material of the semiconductor layer 100 is silicon (Si) or silicon carbide (SIC).

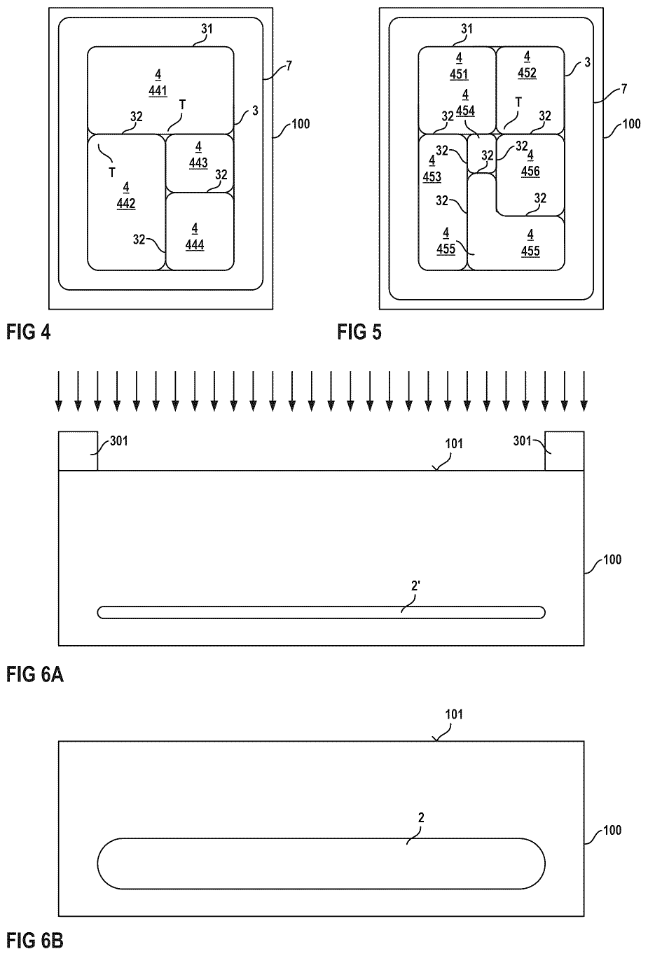

The isolating grid 3 provides for a junction isolation between the device regions 4 of the second doping type. For this, the isolating grid 3 includes a doped region of the first doping type complementary to the second doping type. Thus, a PN junction is formed between the isolating grid 3 and each of the device regions 4, so that two device regions 4 are junction isolated from each other by two PN junctions that are formed by a portion of the isolating grid 3 located between the two device regions and by a respective portion of each of the two device regions 4. The PN junctions formed between the isolating grid 3 and each of the device regions 4 are represented by diodes in the examples illustrated in FIGS. 1-3. For the ease of illustration, the diodes are not illustrated in FIGS. 4 and 5. The diodes illustrated represent a scenario in which the doped region of the isolating grid 3 is an N-type region and the device regions 4 are P-type regions. Thus, in this example, the first doping type is an N-type and the second doping type is a P-type.

This, however, is only an example. It is also possible to implement the device regions as N-type regions and the doped region of the isolating grid 3 as a P-type region. in this example, the polarity of the diodes is reversed.

According to one example, the semiconductor layer 100 has a basic doping of the second doping type, wherein the basic doping of the semiconductor layer 100 defines a basic doping of the second doping type of the device regions 4. According to one example, a doping concentration of the basic doping of the semiconductor layer 100 is selected from a range of between 1E13 cm⁻³ and 1E17 cm⁻³. According to one example, the basic doping of the semiconductor layer 100 is at least approximately homogeneous. According to another example, the basic doping of the semiconductor layer 100 varies in a vertical direction, which is a direction perpendicular to the first surface 101.

A maximum of the doping concentration of the doped region of the first doping type of the isolating grid 3 is higher than 1E18 cm⁻³, higher than 1E19 cm⁻³, or even higher than 1E20 cm⁻³. As explained herein further below, the doped regions of the isolating grid 3 may be formed by a diffusion process. In this case, the doping concentration of the doped region of the isolating grid 3 may vary and, in particular, may decrease towards those regions having the basic doping of the semiconductor layer 100.

According to one example, the isolating grid 3 includes an isolating ring 31 and at least one isolating bridge 32 formed within the isolating ring 31. Referring to FIGS. 2-5, the isolating ring, in lateral directions of the semiconductor layer 100 forms a closed loop. “Lateral directions” of the semiconductor layer 100 are directions that are essentially parallel to the first surface 101. The at least one isolating bridge 32 adjoins the isolating ring and, together with the isolating ring 31 defines the device regions 4. The number and the lengths of the individual isolating bridges 32 is arbitrary. Some examples of isolating bridges 32 and the resulting device regions 4 are illustrated in FIGS. 2-5 and explained herein further below.

The buried region 2 together with the isolating ring 31 extending from the first surface 101 to the buried region 2 enclose the device regions 4 within the semiconductor layer 100. A section of the semiconductor layer 100 adjoining the isolating ring 31 and the buried region 2 from outside the arrangement with the device regions 4 is referred to as outer region 140 of the semiconductor layer 100. At least those sections of the outer region 140 that adjoin the isolating ring 31 and the buried region 2 may have the basic doping of the second doping type of the semiconductor layer 100. The region of the semiconductor layer 100 enclosed by the isolating rings 31 and the buried region 2 is referred to as “inner region” 130 in the following.

The isolating ring 31 and the buried region 2 provide for a junction isolations between the device regions 4 and the outer region. That is, a PN junction is formed between the outer region 140 and the isolating ring 31 and between the outer region 140 and the buried region 2. Furthermore, a PN junction is formed between each device region 4 and the buried region 2 and a PN junction is formed between the isolating grid 3 and each of the device regions 4 that adjoin the isolating ring 31.

In each of the device regions 4 an electronic device, such as a transistor device, a resistor, or a capacitor, can be integrated. Such electronic devices are not illustrated in FIGS. 1-5. Examples of electronic devices that can be integrated in the individual device regions 4 are explained herein further below.

According to one example, the semiconductor layer 100 is a semiconductor substrate of the second doping type. According to another example, illustrated in dashed lines in FIG. 1, the semiconductor layer 100 is an epitaxial layer grown on a substrate 200. The substrate 200 can have the first doping type or the second doping type. According to one example, the epitaxial layer forming the semiconductor layer 100 includes several sub-layers that are formed one above the other. According to one example, forming the semiconductor layer 100 and the buried region 2 includes forming a first sub-layer of the epitaxial layer 100, implanting dopant atoms for forming the buried region 2 into the first sub-layer, and forming at least one further sub-layer on top of the first sub-layer after implanting the dopant atoms.

Referring to the above, the isolating grid 3 includes at least one isolating bridge 32. Thus, the isolating grid 3 may include exactly one isolating bridge 32 or may include several isolating bridges 32. Some examples for implementing the isolating grid 3 are illustrated in FIGS. 2-5 and explained in the following.

In the example illustrated in FIG. 2, the isolating grid 3 includes exactly one isolating bridge 32. The isolating bridge 32 divides the region of the semiconductor layer 100 inside the isolating ring 31 into two device regions 4, a first the device region 421 and a second device region 422. Just as an example, the first and second device regions 421, 422 according to FIG. 2 have different sizes. It is also possible to implement the device regions 421, 422 to have essentially identical sizes.

In the example illustrated in FIGS. 3, the isolating grid 3 includes three isolating bridges. A first isolating bridge divides the inner region 130 into two portions. A second isolating bridge divides one of the two portions defined by the first isolating bridge into first and second device regions 431, 432, and a third isolating bridge divides the other one of the two portions defined by the first isolating bridge into third and fourth device regions 433, 434.

In the example illustrated in FIG. 4, the isolating grid 3 includes a first isolating bridge that divides the inner region into two portions, wherein one of these portions forms a first device region 441. The other one of these portions is divided into two sub-portions. One of these sub-portions forms a second device region 442. The other one of these sub-portions is divided into a third device region 443 and a fourth device region 444 by a third isolating bridge.

In the examples illustrated in FIGS. 2-4, each of the device regions 4 is partially defined by the isolating ring 31. That is, each of the device regions 4 adjoins the isolating ring 31. However, as can be seen from FIG. 5, this is only an example.

The semiconductor arrangement according to FIG. 5 includes one device region 454 that is only defined by isolating bridges and that is surrounded by further device regions 451, 452, 453, 455, 456, and 457.

In the examples illustrated in FIGS. 2-4, the device regions are essentially rectangular in each include four outer corners each adjoining two sides of the respective device region. This, however, is only an example. It is also possible to implement one or more device regions as L-shaped or T-shaped regions, for example.

One example of an L-shaped device region 455 is illustrated in FIG. 5. The L-shaped device region 455 includes five outer corner and an inner corner 4551. A T-shaped device region, which is not illustrated, may include two inner corners of the type illustrated in FIG. 5. Basically, using bridge regions 32, device regions with an arbitrary shape, that is, with an arbitrary number of inner and outer corners can be formed.

As can be seen from FIGS. 2-5, using the isolating bridges 32 the inner region 130 can arbitrarily be segmented in order to define an arbitrary number of device regions with arbitrary sizes. The size of the individual device regions 4 can be adjusted dependent on the size or the number of semiconductor devices to be integrated in each device region 4.

During operation of the semiconductor arrangement, the isolating grid 3 may be connected to a circuit node having a predefined electrical potential. The buried region 2, which adjoins the isolating grid 3, is connected to the same electrical potential as the isolating grid 3. If the first doping type is an N-type and the second doping type is a P-type, for example, the predefined electrical potential applied to the isolating grid 3 and the buried region 2 may be the highest electrical potential occurring in the electronic circuit. In this case, electrical potentials of the device regions 4 are lower or equal to the highest electrical potential. In this way, the PN junctions formed between the device regions 4 on one side and the isolating grid 3 and the buried region 2 on the other side are reverse biased. In this example, the outer region 140 may be connected to an electrical potential that is lower than the electrical potential of the isolating grid 3 in order to reverse bias the PN junction between the isolating ring 31 and the buried region 2 on one side and the outer region 140 on the other side. The electrical potential of the outer region 140 may be higher or lower than the electrical potentials of the device regions 4. According to one example, the electrical potential of the outer region 140 is the lowest electrical potential occurring in the electronic circuit. In this example, the electrical potential of the outer region 140 is equal to or lower than the electrical potential of each of the device regions 4.

If the first doping type is a P-type and the second doping type is an N-type, the predefined electrical potential applied to the isolating grid 3 and the buried region 2 may be the lowest electrical potential occurring in the electronic circuit. In this example, the outer region 140 or any inner region 4 portion (potential) may be connected to the highest electrical potential occurring in the electronic circuit.

For connecting the outer region 140 to a predefined electrical potential, which may be the lowest electrical potential or the highest electrical potential occurring in the electronic circuit, a first contact ring 7 may be arranged in the outer region 140. Referring to FIGS. 2-5, the first contact ring 7 may be arranged spaced apart from the isolating ring 31 and surround the isolating ring 31 in lateral directions. According to one example, the first contact ring 7 is a doped region of the second doping type and having a higher doping concentration than the basic doping of the semiconductor layer 100. According to one example, the doping concentration of the first contact ring is higher than 1E18 cm⁻³ or even higher than 1E19 cm⁻³.

In the semiconductor arrangement explained above, the isolating grid 3, which defines at least two device regions 4, provides for a space-saving and flexible segmentation of the semiconductor layer 100 into the individual device regions 4. Each isolating bridge 32, for example, is shared by at least two device regions 4. Thus junction isolations for each of the device regions are provided in a space-saving manner.

Some examples for forming the buried region 2 and the isolating grid 3 are explained in the following.

FIGS. 6A and 6B illustrate one example of a method for forming the buried region 2. Referring to FIG. 6A, the method includes implanting first type dopant atoms via the first surface 101 into the semiconductor layer 100 to form an implanted region 2′ that includes dopant atoms of the first doping type. The implanted region 2′ is spaced apart from the first surface 101. A distance between the first surface 101 and the implanted region 2′ can be adjusted by suitably selecting the implantation energy in the implantation process thereby taking into account the decided implantation dose. Basically, the higher the implantation energy, the larger the distance between the first surface 101 and the implanted region 2′. Furthermore, the higher the implantation dose, the lower the implantation depth.

According to one example, the process of forming the implanted regions 2′ includes forming an implantation mask 301 above the first surface 101. The implantation mask 301 includes an opening that defines a size and a position of the implanted region 2′. Through the opening in the implantation mask 301, the dopant atoms are implanted into the semiconductor body 100. The remainder of the semiconductor layer 100 is protected by the implantation mask 301 from having dopant atoms implanted.

Referring to FIG. 6B, the process further includes an annealing process in which the semiconductor layer 100 is annealed in order to activate the implanted dopant atoms and form the buried region 2 based on the implanted region 2′. The implanted dopant atoms may diffuse in the annealing process, so that the buried region 2 may have larger dimensions than the implanted region 2′. Furthermore, the annealing process may result in the growth of an oxide layer at the first surface 101, which may help to prevent outgassing of the implanted dopant atoms.

In the example illustrated in FIGS. 6A and 6B, the dopant atoms are implanted into the semiconductor layer 100 via the first surface 101. In the finished semiconductor arrangement, the first surface 101 is the surface from which the isolating grid 3 extends down to the buried region 2. However, implanting the dopant atoms into the first surface 101 for forming the buried region 2, is only an example. According to another example (not illustrated) the dopant atoms are implanted into the semiconductor layer 100 through a second surface of the semiconductor layer 100 opposite the first surface 101.

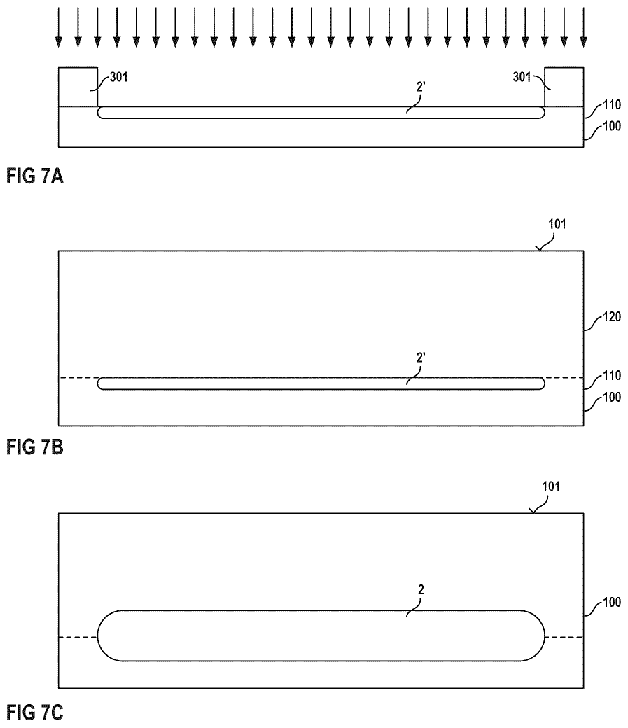

FIGS. 7A-7C illustrate a modification of the method according to FIGS. 6A-6B. The method according to FIG. 7A-7C is different from the method according to FIGS. 6A-6B in that, as illustrated in FIG. 7A, the implanted region 2′ is formed in a first portion 110 of the semiconductor layer 100 before, as illustrated in FIG. 7B, a second portion 120 of the semiconductor layer 100 is formed on top of the first portion 110. Forming the second portion 120 includes an epitaxial growth process, for example. Referring to FIG. 7C, the annealing process for forming the buried region 2 based on the implanted region 2′ may take place before or after forming the second portion 120 on top of the first portion 110. The first portion 110 is a semiconductor substrate or is an epitaxial layer formed on top of a substrate, for example. In the process of forming semiconductor devices in the device regions 4, further annealing processes may take place. These further annealing processes may cause a further diffusion of the dopant atoms in the buried region 2 and may therefore “broaden” the buried region 2 further.

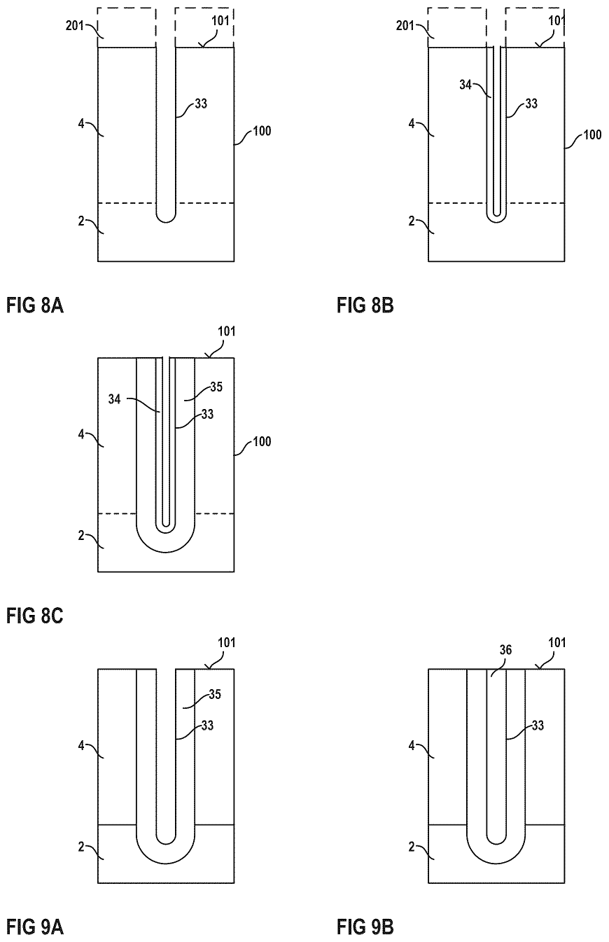

FIGS. 8A-8C illustrate one example of a method for forming the isolating grid 3. It should be noted that FIGS. 8A-8C each illustrate a vertical cross-sectional view of only one portion of the isolating grid 3 during the manufacturing process.

Referring to FIG. 8A, forming the isolating grid 3 includes forming at least one trench 33 that extends from the first surface 101 into the semiconductor layer 100. According to one example, the at least one trench 33 essentially extends in a vertical direction of the semiconductor layer 100. “The vertical direction” is a direction that is essentially perpendicular to the first surface 101. Sidewalls of the at least one trench 33 may be essentially vertical or may be tapered.

Forming the trench may include an etching process in which an etch mask (illustrated in dashed lines) is formed on top of the first surface 101. In a conventional way, the etch mask 201 includes an opening in which portions of the surface 101 are not covered and that that defines the position of the at least one trench 33.

According to one example, a trench width, which is a minimum dimension of the at least one trench 33 in a lateral direction, is in a range of between 0.4 micrometers (μm) and 5 micrometers, in particular between 1 micrometer and 3 micrometers. A trench depths, which is the dimension of the trench 33 in the vertical direction, is in a range of between 5 micrometers and 30 micrometers, in particular between 10 micrometers and 15 micrometers. According to one example, the aspect ratio, which is the ratio between the trench depth and the trench width is in a range of between 5 and 40. If the trench 33 has tapered sidewalls, the trench width used for calculating the aspect ratio is an average of the trench width over the depth of the trench 33.

Referring to FIG. 8B, the method includes forming a dopant source 34 in the at least one trench 33. according to one example, the dopant source 34 is a layer including dopant atoms of the first doping type that can be diffused from the dopant source 34 into semiconductor region surrounding the at least one trench 33. The dopant source 34 at least covers sidewalls and a bottom of the at least one trench 33. In the example illustrated in FIG. 8B, the dopant source 34 completely fills the at least one trench 33. According to another example (not illustrated) the dopant source only covers sidewalls and a bottom of the at least one trench 33.

According to one example, the surface 101 of the semiconductor layer 100 is covered by a protection layer during the process of forming the dopant source 34. The protection layer protects the surface 101 outside the trench 33 from having the dopant source 34 formed thereon. According to one example illustrated in FIG. 8B, the protection layer is the etch mask 201 used in the process of forming the at least one trench.

According to one example, the dopant source 34 includes a silicate glass. According to one example, the first doping type is an N-type. In this example, the silicate glass is a phosphosilicate glass (PSG), for example. PSG includes phosphorus (P) atoms as N-type dopant atoms. According to another example, the first doping type is a P-type. In this example, the silicate glass is borosilicate glass (BSG), for example. BSG includes boron (B) atoms as P-type dopant atoms.

According to one example illustrated in FIG. 8B, the layer forming the dopant source 34 is formed such that it covers sidewalls and a bottom of the at least one trench 33 and that a residual trench remains. This makes it easier to remove the dopant source 34, if desired, later on. According to another example (not illustrated) the layer forming the dopant source 34 entirely fills the at least one trench 33.

Referring to FIG. 8C, the method further includes an annealing process in which the second type dopant atoms are diffused from the dopant source 34 into semiconductor regions of the semiconductor layer 100 surrounding the trench 33 to form the doped region 35 of the first doping type of the isolating grid 3.

It should be noted that the isolating grid 3 may be formed before forming the buried region 2 or may be formed after forming the buried region 2. For this reason, the buried region 2 is illustrated in dashed lines in FIGS. 8A-8C. Furthermore, the same annealing process can be used for activating and diffusing the implanted dopant atoms forming the buried region 2, and for diffusing the dopant atoms from the dopant source 34 into the semiconductor layer 100. Alternatively, two different annealing processes are used for activating the implanted dopant atoms and for diffusing the dopant atoms from the dopant source 34. In each case, the trench depth of the at least one trench 33 is adapted to the vertical position of the implanted regions 2′ such that after the at least one annealing process the doped region 35 of the isolating grid 3 adjoins the buried region 2 or extends into the buried region 2. “The vertical position of the implanted regions 2′” is the position spaced apart from the first surface 101 in a direction that is essentially perpendicular to the first surface 101.

Referring to one example illustrated in FIGS. 9A-9B, the method may further include removing the dopant source 34 from the at least one trench 33 and filling the trench 33 with a filling layer 36. FIG. 9A illustrates the arrangement after removing the dopant source 34 from the trench 33, and FIG. 9B illustrates the arrangement after filling the trench 33 with the filling layer 36.

The filling layer 36 includes an electrically conducting or non-conducting material. According to one example, the filling layer 36 is a homogeneous layer of only one material. According to another example, the filling layer 36 includes a layer stack with two or more sub-layers of different materials. According to one example, at least one of the sub-layers is electrically conducting and at least another one of the sub-layers is non-conducting.

According to one example, the filling layer 36 is non-conducting and includes a dielectric layer that covers sidewalls and the bottom of the at least one trench 33 after removing the dopant source 34, and a non-doped polysilicon layer on top of the dielectric layer. The dielectric layer is an oxide layer, for example. If the filling layer 36 is non-conducting, the electrically conducting doped region 35 can be connected to a circuit node having the desired predefined electrical potential in order to connect the isolating grid 3 to the circuit node having the predefined electrical potential.

According to another example, the filling layer 36 is electrically conducting and includes doped polysilicon or a metal, for example. If the filling layer 36 is conducting, the filling layer 36 and/or the doped region 35 can be connected to the circuit node having the desired predefined electrical potential in order to connect the isolating grid 3 to the circuit node having the predefined electrical potential.

According to another example, the filling material 36 is electrically insulating. In this example, the filling material 36 may include an oxide. Furthermore, in this example, the doped region 35 is connected to a circuit node having the desired predefined electrical potential.

Referring to the above, forming the isolating grid 3 includes forming at least one trench in the semiconductor layer 100. According to one example, forming the isolating grid 3 includes forming a plurality of trenches that are spaced apart from each other. According to one example, a distance between neighboring trenches 33 is so small that the doped regions 35 formed along the sidewalls of the trenches overlap and form a contiguous doped region of the first doping type.

Referring to FIGS. 2-5, the isolating grid 3 may include T-portions. At a T-portion an isolating bridge 32 adjoins another isolating bridge 32 or the isolating ring 31 and is essentially perpendicular to the other isolating bridge 32 or the isolating ring 31. In the example illustrated in FIG. 1, T-portions occur in those regions in which the isolating bridge 32 adjoins the isolating ring 31. In the examples illustrated in FIGS. 3-5 T-type regions occur in those regions in which isolating bridges 32 adjoin the isolating ring 31 and also occur in those regions in which two isolating bridges 32 adjoin one another.

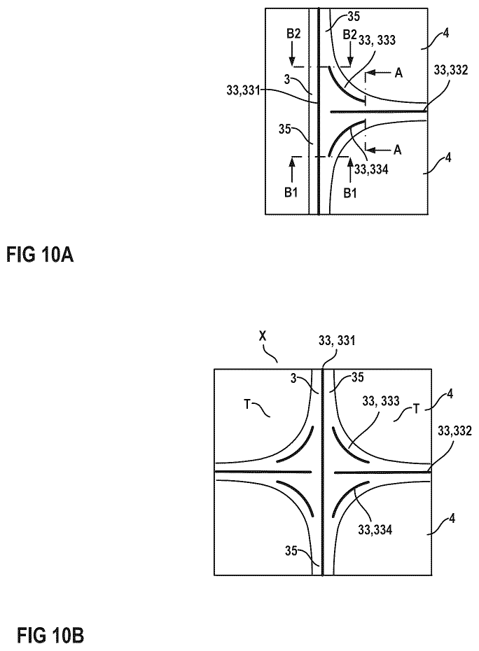

One example of a T-portion is illustrated in FIG. 10A in greater detail. More specifically, FIG. 10A shows a top view of one T-portion of the isolating grid 3. The isolating grid 3 illustrated in FIG. 10A is based on one of the examples illustrated in FIGS. 8A-8C or 9A-9B and includes several trenches 33. The trenches 33 are illustrated by bold lines in FIG. 10. After the end of forming the isolating grid 3 the trenches may still be filled with the dopant source 34, as illustrated in FIG. 8C, or may be filled with an electrically conducting or an electrically insulating filling material 36, as illustrated in FIG. 9B.

The trenches 33 illustrated in FIG. 10A include a first trench 331 and a second trench 332. The second trench 332 is essentially perpendicular to the first trench 331. Furthermore, a longitudinal end of the second trench 332 is spaced apart from the first trench 331. According to one example, a distance between the longitudinal end of the second trench 332 and the first trench 331 is between 0.5 micrometers and 2 micrometers, for example. The first trench 331 is a portion of the isolating rings 31 or is a portion of an isolating bridge 32, for example. The second trench 332 is a portion of an isolating bridge 32.

Referring to FIGS. 10A-10B, the T-portion further includes a third trench 333 and a fourth trench 334. The third trench 333 is arranged in a first corner defined by the first trench 331 and the second trench 332, and the fourth trench 334 is arranged in a second corner defined by the first trench 331 and the second trench 332. The second corner is different from the first corner. Each of the third and fourth trenches 333, 334 is spaced apart from each of the first and second trenches 331, 332. Furthermore, each of the third and fourth trenches 333, 334 is curved. The third and fourth trenches 333, 334 may have the same curvature. This, however, is only an example. It is also possible to implement the third and fourth trenches 333, 334 to have different curvatures.

As explained above, dopant atoms for forming the doped region 35 are diffused from a dopant source 34 (not illustrated in FIGS. 10A-10B) arranged in the trenches 33 into the surrounding semiconductor material of the semiconductor layer 100. Thus, as can be seen from FIG. 10, a curvature of the second and fourth trenches 333, 334 essentially defines a curvature of the doped region 35 of the isolating grid 3 in a corner a region of the isolating grid 3. A “corner region” of the isolating grid 3 is a region in which a first portion of the isolating grid adjoins a second portion of the isolating grid that is essentially perpendicular to the first portion.

Referring to the above, a PN junction is formed between the isolating grid 3 and the device region 4. It is commonly known that an electric field occurs at a PN junction that is reverse biased. Curved PN junctions can be critical as the electric field resulting from a given reverse biasing voltage applied to the PN junction can be higher at a curved PN junction than at a linear PN junction. Basically, at a given reverse biasing voltage applied to the PN junction, the stronger the curvature, the higher the electric field. Furthermore, an Avalanche breakdown may occur when the electric field reaches a predefined critical field strength.

Forming the T-type portion of the isolating grid 3 illustrated in FIG. 10A only based on the first and second trenches 331, 332 may result in a strong curvature of the PN junction between the doped region 35 of the isolating grid 3 and the device region 4. In contrast, by additionally providing the third and fourth trenches 333, 334 the curvature of the doped region 35 and, therefore, the curvature of the PN junction formed between the doped region 35 and device region 4 can be reduced, resulting in a reduction of the field strength of the electric field in the corner region. This makes it possible to use a single isolating bridge 32 for junction isolating two neighboring device regions 4 from one another. Basically, the lower the curvature of the third and fourth trenches 333, 334 the higher the voltage that can be absorbed by the PN junction. In the same semiconductor body 100 T-type portions of the isolating grid 3 with different curvatures of the third and fourth trenches 333, 334 can be implemented, thereby making it possible to implement device regions 4 that have different voltage blocking capabilities relative to the isolating grid 3.

Implementing the first, second, third, and fourth trenches 331, 332, 333, 334 spaced apart from each other makes it possible to partially fill or fill each of the trenches 331-334 in the process according to FIGS. 8A-8C or 9A-9B at each position in essentially the same way. This would be different if, for example, the first trenches 331 would merge into the second trench 332. At the position where the two trenches 331, 332 would merge a cross-sectional area would be locally increased which would result in higher risk of the formation of a void during the filling process. The same would apply if the third and fourth trenches 333, 334 would merge into one or both of the first and second trenches 331, 332.

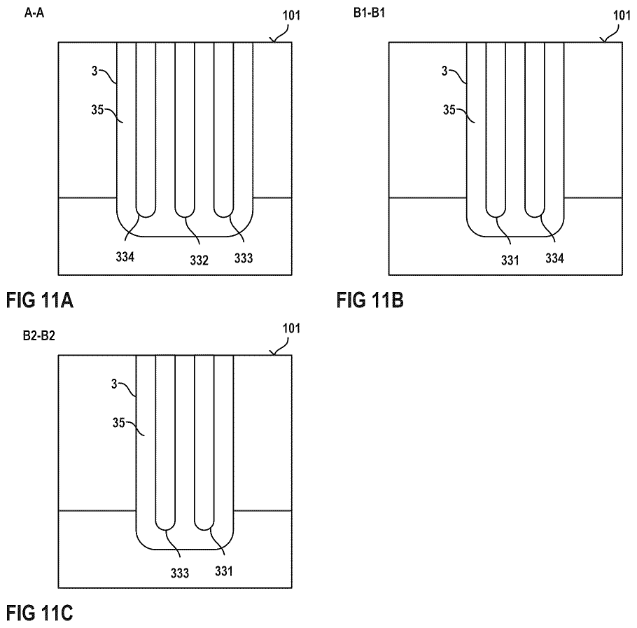

A distance from the third trench 333 to the first and second trenches 331, 332 is such that the doped region 35 formed around the third trench 333 based on the dopant source 34 (not illustrated in FIG. 10) in the third trench 333 adjoins the doped regions 35 formed along the first and second trenches 331, 332 based on the dopant source 34 (not illustrated in FIG. 10) in the first and second trenches 331, 332 and connects these doped regions formed along the first and second trenches 331, 332 with each other. Equivalently, a distance from the fourth trench 334 to the first and second trenches 331, 332 is such that the dopant region formed around the fourth trench 334 adjoins the doped regions 35 formed along the first and second trenches 331, 332 and connects the doped regions formed along the first and second trenches 331, 332 with each other. This is illustrated in FIGS. 11A-11C.

FIG. 11A shows a vertical cross-sectional view of the isolating grid 3 in a vertical section plane A-A illustrated in FIG. 10A that is essentially perpendicular to the second trench 332 and cuts through the second, third, and fourth trenches 332, 333, 334. FIG. 11B shows a vertical cross-sectional view of the isolating grid 3 in a vertical section plane B1-B1 illustrated in FIG. 10A that is essentially perpendicular to the first trench 331 and cuts through the first trench 331 and the fourth trench 334. FIG. 11C shows a vertical cross-sectional view of the isolating grid 3 in a vertical section plane B2-B2 illustrated in FIG. 10A that is essentially perpendicular to the first section plane A-A and cuts through the first trench 331 and the third trench 333.

As can be seen from FIG. 11A the doped regions 35 formed around the third and fourth trenches 333, 334 adjoin the doped region 35 formed around the second trench 332. As can be seen from FIG. 11B, the dopant region 35 formed around the fourth trench 334 adjoins the doped region 35 formed along the first trench 331. Equivalently, as can be seen from FIG. 11C, the doped region formed around the third trench 333 adjoins the doped region formed along the first trench 331.

As can be seen from FIG. 10A, distances between the third and fourth trenches 333, 334 on the one hand and the second trench 332 on the other hand increase towards the first trenches 331. Equivalently, distances between the third and fourth trenches 333, 334 on the one hand and the first trench 331 on the other hand increase towards the second trench 332. This may have the effect that not to the entire region arranged between the third trench 333, the first trench 331 and the second trench 332 and not the entire region arranged between the fourth trench 334, the first trenches 331 and the second trench 332 is covered by the doped region 35. This, however, is not critical. In each case, the doped region 35 is a contiguous doped region along each of the first, second, third, and fourth trenches 31, 32, 33, 34.

FIG. 10B shows a modification of the T-type portion illustrated in FIG. 10A. The arrangement illustrated in FIG. 10B results from mirroring the arrangement illustrated in FIG. 10A along a line defined by the first trench 331 so that the arrangement includes 2 T-type portions that have the first trench 331 in common. This combination of 2 T-type portions may be referred to as X-type portion.

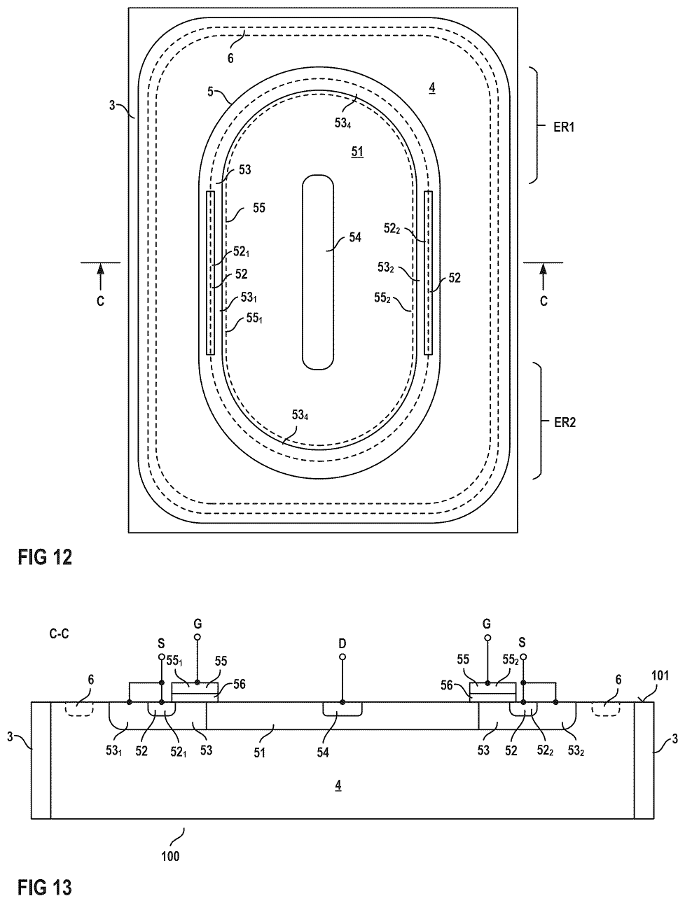

FIGS. 12 and 13 illustrate one example of a semiconductor device that may be integrated in the device region 4. The semiconductor device illustrated in FIGS. 12 and 13 is a lateral transistor device. FIG. 12 shows a top view of the transistor device and FIG. 13 shows a vertical cross-sectional of the transistor device in a section plane C-C illustrated in FIG. 12.

Just for the purpose of illustration, the transistor device 5 illustrated in FIGS. 12 and 13 is a MOSFET. In particular, the MOSFET is a MOSFET having a channel of the first doping type, so that the MOSFET is an N-type MOSFET (N-channel MOSFET) when the first doping type is an N-type and a P-type MOSFET (P-channel MOSFET) when the second doping type is a P-type.

In this example, the transistor device 5 includes a drift region 51 of the first doping type, a drain region 54 of the first doping type adjoining the drift region 51, a body region 53 of the second doping type adjoining the drift region 51 and spaced apart from the drain region 54, and a source region 52 of the first doping type separated from the drift region 51 by the body region 53. Each of the drift region 51, the drain region 54, the body region 53, and the source region 52 is a doped region formed within the device region 4 of the semiconductor body 100.

The drift region 51, the source region 52, the body region 53, and the drain region 54 are active device regions of the transistor device 5. Forming the active device regions of the transistor device 5 may include implanting dopant atoms into the device region 4 and may include a thermal process for activating the implanted dopant atoms. Referring to the above, the device region 4 has a basic doping of the second doping type.

According to one example, sections of the device region 4 that have the basic doping concentration remain after forming the active device regions so that at least in some sections doped regions 4 having the basic doping concentration of the second doping type of the device which are arranged between the active device regions and the isolating grid 3.

Doping concentrations of the source and drain regions 52, 54 are higher than 1E19 cm⁻³, for example, and can be as high as 1E21 cm⁻³, for example. The doping concentration of the drift region 51 is selected from between 1E14 cm⁻³ and 1E18 cm⁻³, for example, and the doping concentration of the body region 53 is selected from between 1E14 cm⁻³ and 1E18 cm⁻³, for example.

Referring to FIGS. 12 and 13, the transistor device 5 further includes a gate electrode 55. The gate electrode 55 is arranged adjacent to the body region 53 and is dielectrically insulated from the body region 53 by a gate dielectric 56. In a conventional way, the gate electrode 55 serves to control a conducting channel in the body region 53 between the source region 52 and the drift region 51. The channel is a channel of the first doping type. That is, the channel is in an N-channel when the first doping type is an N-type and a P-channel when the first doping type is a P-type.

In the example illustrated in FIGS. 12 and 13, the gate electrode 55 is a planar electrode formed on top of a first surface 101 of the semiconductor body 100 and separated from the semiconductor body 100 by the gate dielectric 56. This, however, is only an example. According to another example (not illustrated) the gate electrode 55 is a trench electrode that is formed in a trench extending in a vertical direction of the semiconductor body 100 from the first surface 101 into the semiconductor body 100, and extending in a lateral direction of the semiconductor body 100 from the source region 52 through the body region 53 to the drift region 51. The “vertical direction” is a direction that is essentially perpendicular to the first surface 101. “Lateral directions” are directions that are essentially parallel to the first surface 101.

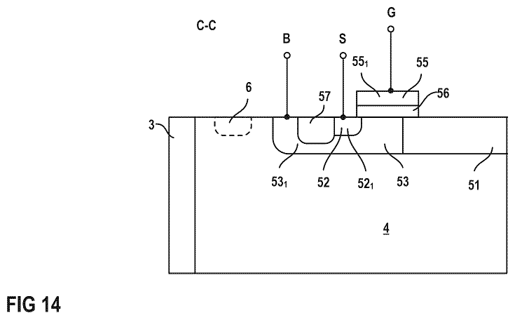

Referring to FIG. 13, the drain region 54 is connected to a drain node D, the gate electrode 55 is connected to a gate node G, and the source region 52 is connected to a source node S. These circuit nodes of the transistor devices 5 may be formed by electrically conducting layers (not illustrated) that may serve to connect the transistor device 5 with electronic devices integrated in device regions 4 other than the one illustrated in FIGS. 12 and 13. Connections between the active device regions 51, 52, 53, 54 and the individual circuit nodes S, G, D are only schematically illustrated in FIG. 14. Connecting active device regions of semiconductor devices to respective circuit nodes, and connecting electronic devices arranged in different device regions of a semiconductor body with each other is commonly known, so that no further explanation is required in this regard.

In the example illustrated in FIGS. 12 and 13, the body region 53 includes two body region sections, a first body region section 531 and a second body region section 532. Each of the first and second body region sections 531, 532 is spaced apart from the drain region 54 in a respective lateral direction. Furthermore, the first and second body region sections 531, 532 are spaced apart from each other such that the drain region 54 is arranged between the first and second body region sections 531, 532. According to one example, distances between the drain region 54 and the first gate region section 531 on one side and between the drain region 54 and the second body region section 532 on the other side are essentially equal, so that the first and second body region sections 531, 532 are symmetrical to each other with respect to the drain region 54. Each of the first and second body region sections 531, 532 is connected to the source node S of the transistor device 5.

Furthermore, in the transistor device illustrated in FIGS. 12 and 13, the source region 52 includes a first source region section 521 that is separated from the drift region 51 by the first body region section 531, and a second source region section 522 that is separated from the drift region 51 by the second body region section 532. Each of the first and second source region sections 521, 522 is connected to the source node S.

Furthermore, in the transistor device according to FIGS. 12 and 13, the gate electrode 55 includes two gate electrode sections, a first gate electrode section 551, and a second gate electrode section 552. The first gate electrode section 551 is adjacent to the first body region section 551 and serves to control a first conducting channel in the first body region section 551 between the first source region section 521 and the drift region 51. The second gate electrode section 552 is adjacent to the second body region section 552 and serves to control a second conducting channel in the second body region section 552 between the second source region section 522 and the drift region 51. Each of the first and second gate electrode sections 551, 552 is connected to the gate node G so that the first and second conducting channel are controlled simultaneously.

According to one example illustrated in FIG. 12, the doped region forming the first and second body region sections 531, 532 forms a closed loop or ring that laterally surrounds the drift region 51 and the drain region 54. According to one example, the body region 53 is formed such that at each position of the body region 53 a (shortest) distance between the body region 53 and the drain region 54 is essentially the same. In this example, the body region 53 includes a third body region section 533 arranged between the first and second body region section 531, 532 in a first edge region ER1 of the device region 4, and a fourth body region section 534 arranged between the first and second body region sections 531, 532 in a second edge region ER2 of the device region 4. The third and fourth body region sections 533, 534 are devoid of having source region sections embedded therein. Furthermore, the first, second, third, and fourth body region sections 531, 532, 533, 534 form a closed loop of the body region 53 around the drift and drain regions 51, 54.

Referring to FIG. 13, the gate electrode 55, in a way similar to the body region 53, may be ring-shaped and, above the first surface 101, may form a closed loop around projections of the drift and drain regions 51, 54 . . . . From the first and second body region sections 531, 532 and the corresponding source region sections 521, 522, the gate electrode 55 is dielectrically insulated by the gate dielectric 56 (out of view in FIG. 12).

According to one example, in the edge regions ER1, ER2 the gate electrode 55 is separated from the semiconductor body 100 by a dielectric layer (out of view in FIG. 12) that is thicker than the gate dielectric 56 and forms a field dielectric. According to another example (not illustrated) the source region 52, in a way similar to the body region 53, forms a closed loop around the drift and drain regions 51, 54. In this example, the source and body regions 52, 53, in the edge regions ER1, ER2, may be separated from the ring-shaped gate electrode 55 by a dielectric layer that is thicker than the gate dielectric 56, so that those sections of the source region 52 that are arranged in the edge regions ER1, ER2 are essentially electrically inactive. That is, essentially no conducting channel is generated in the body region 53 between the source region 52 and the drift region 51 in the edge regions ER1, ER2.

It should be noted that implementing a lateral MOSFET to have two source and body regions sections that are essentially symmetrical is only an example. It is also possible to implement a lateral MOSFET of the type illustrated in FIGS. 12 and 13 to have only one source and body region spaced apart from the drain region.

Referring to the above, in order to electrically insulate the electronic devices integrated in the individual device regions 4 from each other the isolating grid 3 may be connected to the highest electrical potential and each of the device regions 4 may be connected to an electrical potential that is equal to or lower than the highest electrical potential, or the isolating grid 3 may be connected to the lowest electrical potential and each of the device regions 4 may be connected to an electrical potential that is equal to or higher than the lowest electrical potential. Whether the isolating grid 3 is connected to the highest electrical potential or the lowest electrical potential is dependent on the way the PN junction between the isolating grid 3 in the device region 4 is implemented. In a semiconductor arrangement in which the first doping type, which is the doping type of the isolating grid 3, is an N-type and in which the second doping type, which is the doping type of the device regions 4, is a P-type, for example, the isolating grid 3 may be connected to the highest electrical potential and each of the device regions 4 may be connected to an electrical potential that is equal to or lower than the highest electrical potential applied to the isolating grid 3.

As explained above, for connecting the outer region 140 of the semiconductor layer 100 to a predefined electrical potential, the semiconductor arrangement may include the first contact ring 7 which laterally surrounds the isolating grid 3. Similar inner rings 6 may be arranged in the individual device regions 4. The inner ring 6 has a higher doping concentration than the basic doping of the device region 4. According to one example, the doping concentration of the contact ring 6 is at least 10 times the doping concentration of the basic doping. According to one example, the doping concentration of the inner ring 6 is so high that the inner ring 6 cannot entirely be depleted of charge carriers, The inner ring 6 is optional and is therefore illustrated in dashed lines in FIGS. 12 and 13.

According to one example, if the device region 43 has the same doping type as the device region 4, the device region 4 may be connected to the desired electrical potential, such as source of potential, via the body region 53. According to another example, the device region for is connected to desired electrical potential via the inner region 6. For this, the inner region 6 may be connected to a contact electrode (not illustrated in FIG. 13) that is connected to the desired electrical potential, such as source potential.

According to one example, the inner ring 6 is implemented such that a distance between the contact ring 6 and the isolating grid 3, at each position, is essentially the same. The isolating grid 3, in particular the doped regions 35 (not illustrated in FIGS. 12 and 13) of the isolating grid, the inner ring 6 and sections of the device region 4 having the basic doping of the second doping type, form a PN diode. A voltage blocking capability of this PN diode and, therefore, the maximum voltage that can be applied between the isolating grid 3 and the device region 4 is dependent on a distance between the contact ring 6 and the isolating grid 3. Basically, the larger the distance, the higher the voltage blocking capability.

It should be noted that in different device regions 4 the distance between the inner ring 6 and the isolating grid 3 can be different in order to achieve different voltage blocking capabilities. Thus, in device regions 4 in which a rather low voltage between the isolating grid 3 and the electronic device implemented in the device region 4 is to be expected, the distance between the contact ring 6 and the isolating grid 3 can be small, which helps to implement this device region 4 in a space-saving manner. Thus, in the same semiconductor arrangement, the size of the individual device regions 4 can be optimized in view of the electronic devices to be integrated in the individual device regions 4. In the same semiconductor arrangement, voltage blocking capabilities of between several volts and several 10 volts, up to 200 V and more, can be achieved.

Referring to the above, the device region 4, during operation of the semiconductor arrangement, may have an electrical potential that is different from the electrical potential of the isolating grid 3, wherein a voltage difference resulting from the different electrical potentials is absorbed by the PN junction formed between the isolating grid 3 and the device region 4. Referring to the above, the maximum voltage that can be applied between the device region 4 and the isolating grid 3 may be defined by the inner ring 6 and a distance between the inner ring 6 and the isolating grid 3. The desired electrical potential may be applied to the device region 4 in different ways.

According to one example illustrated in FIG. 13, the source node S is connected to the body region 53. In this example, the source node S may serve for applying a predefined electrical potential to the device region 4. The body region 53 has the same doping type as the device region 4 and adjoins the device region 4, so that, by applying a predefined electrical potential to the body region 53 via the source node S, the predefined electrical potential can be applied to the device region 4.

Another example for connecting the device region 4 to a predefined electrical potential is illustrated in FIG. 14. FIG. 14 illustrates an enlarged view of one portion of a device of the type illustrated in FIG. 13. In the example illustrated in FIG. 14, the transistor device, in addition to the source node S, the gate node G, and the drain node D, includes a further device node B, which may be referred to as bulk node. The bulk node B is connected to the body region 53. According to one example, an isolation region 57, such as a STI (shallow trench isolation) is arranged between a section of the body region 53 to which the bulk node B is connected to and the source region 52.

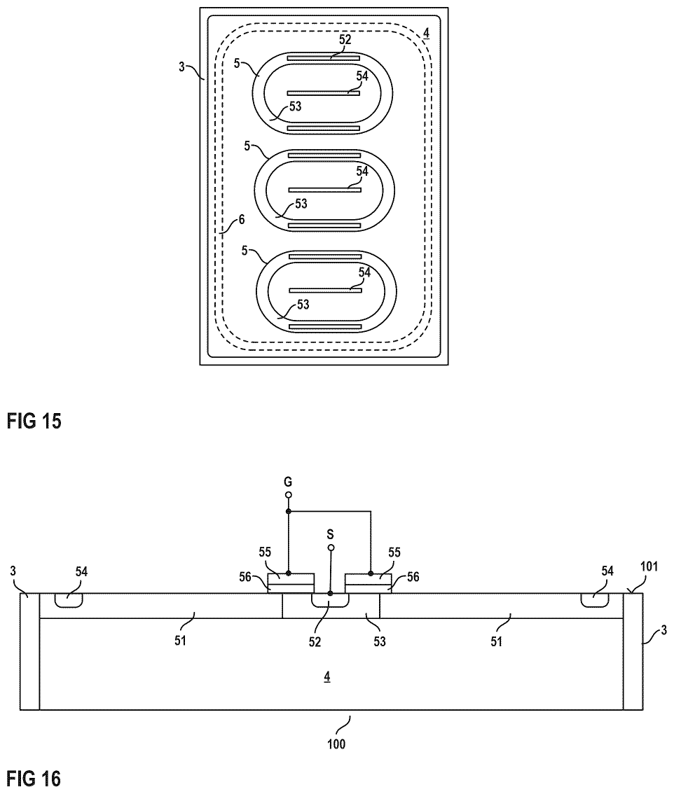

In the example illustrated in FIGS. 12 and 13, one transistor device is integrated in one device region 4. This, however, is only an example. According to another example that is schematically illustrated in FIG. 15, several transistor devices are integrated in one device region 4. In FIG. 14, the transistor devices are only schematically illustrated. A second contact ring 6 (illustrated in dashed lines) may laterally surround the region in which the individual transistor devices are integrated.

In the example illustrated in FIGS. 12 and 13, the transistor device is a first type transistor device, which is a transistor device having, in the conducting state, a channel of the first doping type. In this transistor device, the drift region 51, the source region 52 and the drain region 54 have the first doping type, which is the same doping type as the doped region 35 (not illustrated in FIGS. 12 and 13) of the isolating grid 3, and the body region 53 has the second doping type, which is the same doping type as the basic doping of the device region 4. If, for example, the transistor device is an N-type transistor device, the source and drain regions 54 are N-type regions and the body region 53 and the device region 4 are P-type regions. Referring to the above, in this case, the isolating grid 3 may be connected to the highest electrical potential occurring in the semiconductor arrangement and the device region 4 may be connected to an electrical potential that is equal to or lower than the electrical potential of the isolating grid 3. The drain region 54 may be connected to an electrical potential that is even higher than the electrical potential of the isolating grid 3, wherein a voltage difference between the drain region 54 and the device region 4 is absorbed by a PN junction between the drift region 51 and the device region 4.

FIG. 16 illustrates a vertical cross-sectional view of a first type transistor device according to another example. In this example, the body region 53 and the source region 52 are arranged inside a ring-shaped drain region 54. The ring defined by the drain region 54 is not illustrated in the vertical cross-sectional view according to FIG. 15. The ring defined by the drain region 54 is similar to the ring defined by the source region 52 according to FIGS. 12 and 13.

The source region 52 is embedded in the body region 53 and may have an elongated shape similar to the shape of the drain region in the example illustrated in FIGS. 12 and 13. Above the first surface 101 of the semiconductor body 100, the gate electrode 55 forms a ring around the source region 52. The gate electrode 55 is dielectrically insulated from the semiconductor body 100 by the gate dielectric 56.

Referring to FIG. 16, the drift region 51 is arranged between the body region 53 and the drain region 54, wherein the drain region 54 may be embedded in the drift region 51. According to one example, the drift region 51 extends to the isolating grid 3. The drain region 54 may be spaced apart from the isolating grid 3 (as illustrated) or may adjoin the isolating grid 3 (not illustrated). In this example, the isolating grid 3 and the drain region 54 essentially have the same electrical potential. Furthermore, the transistor device may be operated such that electrical potential of the body region 53 and, therefore, the electrical potential of the device region 4 is such that the PN junction between the device region 4 and the isolating grid 3 is reverse biased. The body region 53 is either connected to the source node S or to a bulk node B. Such connection, however, is not illustrated in FIG. 15.

The semiconductor arrangement is not restricted to have first type transistor devices integrated in the device regions 4.

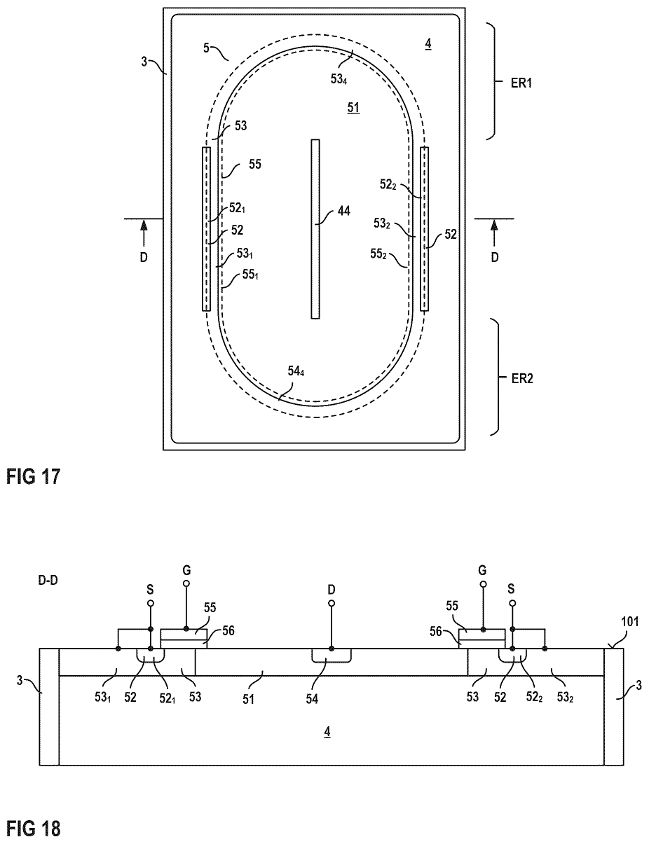

A second type transistor device, which is a transistor device having a channel of the second doping type is illustrated in FIGS. 17 and 18. FIG. 17 shows a top view and FIG. 16 shows a vertical cross-sectional view of the transistor device. The transistor device illustrated in FIGS. 17 and 18 is based on the transistor device illustrated in FIGS. 12 and 13 and is different in that the drift region 51 and the source and drain regions 52, 54 are of the second doping type and the body region 53 is of the first doping type. Furthermore, the transistor device according to FIGS. 17 and 18 is different from the transistor device according to FIGS. 12 and 13 in that the body region, in lateral directions, extends to the isolating grid 3. In the example illustrated in FIG. 17, the body region 53 is connected to the source node S. This, however, is only an example. It is also possible to connect the body region 53 to a bulk node B in the way as illustrated in FIG. 14.

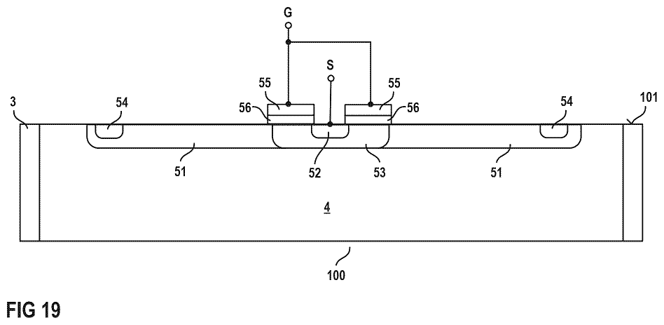

In the example illustrated in FIGS. 17 and 18, the drain region 54 is arranged inside a ring that is defined by the source and body regions 52, 53. Another example of a second type transistor device arranged in the device region 4 is illustrated in FIG. 19.

The transistor device illustrated in FIG. 19 is based on the example illustrated in FIG. 16 and includes a source region 52 of the second doping type that is surrounded by a ring-shaped drain region 54 of the second doping type. The drift region 51 and the drain region 54 are spaced apart from the isolating grid 3. In this type of transistor device, the electrical potential of the device region 4 is defined by the electrical potential of the drain region 54. The body region 53 may either be connected to the source node S or to a bulk node B. A connection between the body region 53 and either the source node S or to the bulk node B, however, is not illustrated in FIG. 19.

Some of the aspects explained above are briefly summarized in the following with reference to numbered examples.

Example 1. A semiconductor arrangement, including: a semiconductor layer having a first surface; a buried region of a first doping type formed in the semiconductor layer spaced apart from the first surface; an isolating grid extending from the first surface to the buried region and including a first region of the first doping type; and device regions of the second doping type adjoining the buried region and isolated from each other by the isolating grid.

Example 2. The semiconductor arrangement according to example 1, further including: a first contact ring of the second doping type laterally surrounding the isolating grid.

Example 3. The semiconductor arrangement according to example 1 or 2, wherein at least one of the device regions includes a second ring of the second doping type.

Example 4. The semiconductor arrangement according to any one of the preceding examples, wherein the isolating grid includes: an isolating ring; and at least one isolating bridge formed within the isolating ring.

Example 5. The semiconductor arrangement according to any one of the preceding examples, wherein the isolating grid further includes at least one isolating trench extending from the first surface to the buried region and surrounded by the first region.

Example 6. The semiconductor arrangement according to example 5, wherein the at least one isolating trench includes a plurality of trenches laterally spaced apart from each other.

Example 7. The semiconductor arrangement according to example 6, wherein the isolating grid includes T-shaped portions, wherein each T-shaped portion includes: an elongated first trench; an elongated second trench at least approximately perpendicular to the first trench; a curved third trench arranged in a first corner defined by the first trench and the second trench; and a curved fourth trench arranged in a second corner defined by the first trench and the second trench.

Example 8. The semiconductor arrangement according to example 7, wherein two T-shaped portions share an elongated first trench and form an X-shaped portion.

Example 9. The semiconductor arrangement according to any one of examples 6 to 8, wherein the trenches are filled with a dopant source.

Example 10. The semiconductor arrangement according to any one of examples 6 to 8, wherein the trenches are filled with an electrically conducting or electrically isolating filling material.

Example 11. The semiconductor arrangement according to any one of the preceding examples, further including: at least one of semiconductor device integrated in each of the device regions.

Example 12. The semiconductor arrangement according to example 11, wherein at least one of the device regions has at least two semiconductor devices integrated therein.

Example 13. The semiconductor arrangement of example 11 or 12, wherein the at least one semiconductor device is selected from the group consisting of, a transistor; a resistor; a diode; a capacitor.

Example 14. The semiconductor arrangement according to example 13, wherein the transistor is selected from the group consisting of: a MOSFET; a JFET; a BJT; an IGBT.

What is claimed is:

1. A semiconductor arrangement, comprising:
a semiconductor layer having a first surface;
a buried region of a first doping type formed in the semiconductor layer spaced apart from the first surface;
an isolating grid extending from the first surface to the buried region and comprising a first region of the first doping type; and
a plurality of device regions of the second doping type adjoining the buried region and isolated from each other by the isolating grid.

2. The semiconductor arrangement of claim 1, further comprising:
a first contact ring of the second doping type laterally surrounding the isolating grid.

3. The semiconductor arrangement of claim 1, wherein at least one of the device regions comprises a second ring of the second doping type.

4. The semiconductor arrangement of claim 1, wherein the isolating grid comprises:
an isolating ring; and
at least one isolating bridge formed within the isolating ring.

5. The semiconductor arrangement of claim 1, wherein the isolating grid further comprises at least one isolating trench extending from the first surface to the buried region and surrounded by the first region.

6. The semiconductor arrangement of claim 5, wherein the at least one isolating trench comprises a plurality of trenches laterally spaced apart from each other.

7. The semiconductor arrangement of claim 6, wherein the isolating grid comprises a plurality of T-shaped portions, wherein each T-shaped portion comprises:
an elongated first trench;
an elongated second trench at least approximately perpendicular to the first trench;
a curved third trench arranged in a first corner defined by the first trench and the second trench; and
a curved fourth trench arranged in a second corner defined by the first trench and the second trench.

8. The semiconductor arrangement of claim 7, wherein two T-shaped portions share an elongated first trench and form an X-shaped portion.

9. The semiconductor arrangement of claim 6, wherein the trenches are filled with a dopant source.

10. The semiconductor arrangement of claim 6, wherein the trenches are filled with an electrically conducting or electrically isolating filling material.

11. The semiconductor arrangement of claim 1, further comprising:
at least one of semiconductor device integrated in each of the device regions.

12. The semiconductor arrangement of claim 11, wherein at least one of the device regions has at least two semiconductor devices integrated therein.

13. The semiconductor arrangement of claim 11, wherein the at least one semiconductor device is selected from the group consisting of:
a transistor;
a resistor;
a diode; and
a capacitor.

14. The semiconductor arrangement of claim 13, wherein the transistor is selected from the group consisting of:
a MOSFET;
a JFET;
a BJT; and
an IGBT.
